(19) United States
(12) Patent Application Publication
(10) Pub. No.: US 2026/0032853 A1
(43) Pub. Date: Jan. 29, 2026

(54) PCIE FORM FACTOR REPLACEABLE COOLING FAN

(71) Applicant: Dell Products L.P., Round Rock, TX (US)

(72) Inventors: Ya-Yun Huang, Taoyuan (TW); Chih-Ta Huang, Taipei (TW); Chien-Yen Hsu, Taipei (TW); Yu-Wei Liao, Taoyuan (TW)

(73) Assignee: Dell Products L.P., Round Rock, TX (US)

(21) Appl. No.: 18/786,853

(22) Filed: Jul. 29, 2024

(51) Int. Cl. H05K 7/20; F04D 25/06

(52) U.S. Cl. CPC H05K 7/20172; F04D 25/0693

(57) ABSTRACT

A replaceable fan module may be swapped with computing components installed in PCIe slots of a chassis that may include one or more IHSs (Information Handling Systems), such as rack-mounted servers. The replaceable fan module may include a centrifugal fan that is mounted on a printed circuit board, where an exhaust of the centrifugal fan is oriented towards openings in a bracket used to fasten the printed circuit board within a PCIe slot of the chassis. The printed circuit board may include pins for electrically coupling the replaceable fan module to the PCIe slot of the chassis, where the pins are arranged according to a PCIe form factor and the replaceable fan module is activated and configured for operation upon coupling of the pins to a connector of the PCIe slot. One or more additional centrifugal fans may be added to the printed circuit board.

### FIELD

The present disclosure relates generally to Information Handling Systems (IHSs), and relates more particularly to airflow cooling of IHSs.

### BACKGROUND

As the value and use of information continues to increase, individuals and businesses seek additional ways to process and store information. One option available to users is Information Handling Systems (IHSs). An IHS generally processes, compiles, stores, and/or communicates information or data for business, personal, or other purposes thereby allowing users to take advantage of the value of the information. Because technology and information handling needs and requirements vary between different users or applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

Groups of IHSs may be housed within data center environments. A data center may include a large number of IHSs, such as servers, that are installed within chassis and stacked within slots provided by racks. A data center may include large numbers of such racks that may be organized into rows in a manner that allows administrators to access components of the IHSs via the front and the back of a rack. In some instances, administrators may be able to service and replace components of a rack-mounted IHS while the IHS remains operational and installed within the rack.

As IHS hardware components, such as processors and memory, have increased in speed and power consumption, the amount of heat produced by such components during operation of an IHS has also increased. Often, the temperatures of IHS hardware components must be kept within a well-defined range in order to prevent overheating, instability, malfunction, and/or damage that would lead to a shortened component lifespan and lowered datacenter reliability. Accordingly, cooling systems are used in IHSs in order to remove heat that is generated by hardware components. In airflow cooling systems, cooling fans are used to force heated air away from a hardware component, and to ventilate heated air away from the heat-generating components of an IHS.

### SUMMARY

In various embodiments, a replaceable fan module may be installed in a chassis including one or more IHSs (Information Handling Systems). The replaceable fan module may include: a first centrifugal fan mounted on a printed circuit board, wherein an exhaust of the first centrifugal fan is oriented towards openings in a bracket for fastening the printed circuit board within a PCIe slot of the chassis; and the printed circuit board comprising a plurality of pins for electrically coupling the replaceable fan module to the PCIe slot of the chassis, wherein the pins are arranged according to a PCIe form factor, and wherein the replaceable fan module is activated and configured for operation upon coupling of the pins to a connector of the PCIe slot.

In some embodiments, the replaceable fan module is substituted by an administrator for a PCIe computing component that is removed from the PCIe slot of the chassis. In some embodiments, the replaceable fan module is connected to a PCIe switch fabric operating on the chassis upon the coupling to the connector of the PCIe slot. In some embodiments, an inlet on top of the first centrifugal fan draws air from within the chassis and directs the drawn air orthogonally via the exhaust towards the openings in the bracket. In some embodiments, the replaceable fan module may include a shroud that is attached to the printed circuit board and that surrounds the first centrifugal fan, except for an exhaust opening oriented towards the openings in the bracket and except for an inlet opening that is oriented towards an interior of the chassis once the replaceable fan module is coupled to the PCIe slot. In some embodiments, the inlet opening in the shroud is oriented towards an end of the printed circuit board that is opposite from the bracket. In some embodiments, the replaceable fan module may include a second centrifugal fan mounted on the printed circuit board, wherein an exhaust of the second centrifugal fan is oriented towards the openings in the bracket. In some embodiments, the replaceable fan module is configured for operation of the first centrifugal fan and the second centrifugal fan upon coupling of the pins to a connector of the PCIe slot.

### BRIEF DESCRIPTION OF THE DRAWINGS

The present invention(s) is/are illustrated by way of example and is/are not limited by the accompanying figures. Elements in the figures are illustrated for simplicity and clarity, and have not necessarily been drawn to scale.

FIG. 1 is a diagram illustrating certain components of a chassis, according to embodiments, that may be reconfigured to utilize a replaceable PCIe form factor fan within the chassis.

FIG. 2 is a circuit diagram illustrating certain components of an IHS, according to embodiments, that may be reconfigured to operate using a replaceable PCIe form factor fan.

FIG. 3A is a perspective-view illustration of a replaceable PCIe fan module, according to embodiments.

FIG. 3B is a top-view illustration of a replaceable PCIe fan module, according to embodiments.

FIG. 3C is a side-view illustration of a replaceable PCIe fan module, according to embodiments.

FIG. 3D is a perspective-view illustration of a replaceable PCIe fan module that includes a shroud, according to embodiments.

FIG. 3E is a side-view illustration of a replaceable PCIe fan module that includes a shroud, according to embodiments.

FIG. 3F is a top-view illustration of a replaceable PCIe fan module that includes a shroud, according to embodiments.

FIG. 3G is a rear-perspective view illustration of a replaceable PCIe fan module that includes a shroud, according to embodiments.

### DETAILED DESCRIPTION

In a data center environment, an IHS may be installed within a chassis, in some cases along with other similar IHSs, such as other server IHSs. A rack may house multiple such chassis and a data center may house numerous racks. Each rack may host a relatively large number of IHSs that are installed as components of chassis, with multiple chassis stacked and installed within each rack. In certain instances, the front and/or rear side(s) of such rack-mounted chassis may include one or more bays or slots that each receive an individual replaceable component. It is preferable that a chassis support multiple different configurations of internal components through adding and removing components from these slots/bays of a chassis, thus expanding the capabilities that may be implemented using the chassis. In some instances, a replaceable component of chassis may not be utilized due to this component not being needed, or due to excessive heat levels in the chassis preventing use of certain heat-generating replaceable components that are installed in the chassis. Accordingly, embodiments support a replaceable fan module that may be substituted for computing components of a chassis, in particular for PCIe form factor computing components.

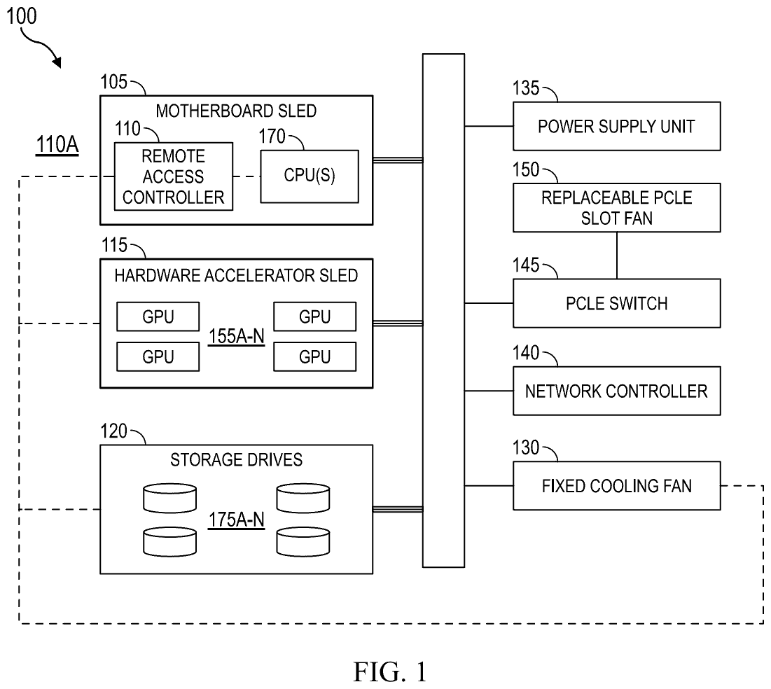

FIG. 1 is a diagram illustrating certain components of a chassis 100, according to embodiments, that may be reconfigured to utilize a PCIe form factor fan within the chassis 100. Embodiments of chassis 100 may include a wide variety of hardware configurations. Such variations in hardware configuration may result from chassis 100 being factory assembled to include components specified by a customer that has contracted for manufacture and delivery of chassis 100. Upon delivery and deployment of a chassis 100, the chassis 100 may be modified by replacing and/or adding various hardware components, in addition to replacement of the removeable IHSs components installed in the chassis. As described in additional detail below, embodiments support capabilities for replacement of PCIe computing, data storage and/or networking components with a PCIe form factor fan module, thus supporting the ability to switch chassis PCIe configurations between performance and additional cooling.

Chassis 100 may include one or more bays that each receive an individual sled (that may be additionally or alternatively referred to as a tray, blade, and/or node), such as motherboard sled 105 and hardware accelerator sled 115. Chassis 100 may support a variety of different numbers (e.g., 4, 8, 16, 32), sizes (e.g., single-width, double-width) and physical configurations of bays. Embodiments may include additional types of sleds that provide various storage, power and/or processing capabilities. For instance, sleds installable in chassis 100 may be dedicated to providing power management or networking functions. Sleds may be individually installed and removed from the chassis 100, thus allowing the computing and storage capabilities of a chassis to be reconfigured by swapping the sleds with different types of sleds, in some cases at runtime without disrupting the ongoing operations of the other sleds installed in the chassis 100. The sleds may be individually coupled to chassis 100 via connectors that correspond to the bays provided by the chassis 100 and that physically and electrically couple the sleds to motherboard sled 105 and/or to one another.

In some embodiments, the sleds that may be added and removed from the chassis 100 may be implemented as PCB-mounted cards that conform to PCIe form factor standards for replaceable components. Once physically connected to PCIe connectors of chassis 100, this hardware may then be logically connected to a PCIe switch fabric of the chassis 100. As described in additional detail below, replaceable PCIe computing components may be swapped out by an administrator for a PCIe form factor fan module 150. Through such swapping of PCIe computing devices with a PCIe form factor fan 150, the capabilities of chassis 100 may be adapted by switching between available cooling and performance capabilities, thus maximizing the use of all available PCIe physical slots that are supported by a chassis.

Multiple chassis 100 may be housed within a rack. Data centers may utilize large numbers of racks, with various different types of chassis installed in various configurations of racks. The modular architecture provided by the sleds, chassis and racks allow for certain resources, such as cooling, power and network bandwidth, to be shared by the sleds installed in chassis 100, thus providing efficiency improvements and supporting greater computational loads.

Chassis 100 may be installed within a rack structure that provides a portion of the cooling utilized by the sleds installed in chassis 100. For airflow cooling, a rack may include one or more banks of cooling fans that may be operated to ventilate heated air from within the chassis 100 that is housed within the rack. In some embodiments, chassis 100 may include a bank of fixed cooling fans 130 that may be operated to ventilate heated air out of the chassis and away from the sleds and other computing components installed within chassis. In this manner, a rack and a chassis 100 installed within the rack may utilize various configurations and combinations of cooling fans to cool the sleds and other components housed within chassis 100. As illustrated in FIG. 1, in embodiments, a chassis may also include a replaceable PCIe-slot fan 150. As described in additional detail below, the PCIe-slot fan 150 may be substituted for other replaceable PCIe hardware components of chassis 100, or at least substituted for other replaceable PCIe hardware that conform to PCIe form factors that define the physical connection and the size parameters for replaceable PCIe hardware.

As described in additional detail below, motherboard sled 105 may implemented in embodiments such that it may be installed within a bay of chassis 100, thus supporting high-density configurations of chassis 100. Motherboard sled 105 may include be a printed circuit board (i.e., motherboard) that includes electrical traces and connectors that are configured to route signals between the various components of chassis 100 that are connected to the motherboard sled 105 and between different components mounted on the motherboard. As illustrated, motherboard sled 105 may include one or more CPU(s) used to execute software programs that include an operating system and that may also include various programs for utilizing and managing the capabilities provided by chassis 100, including managing replaceable PCIe components that are installed in chassis 100.

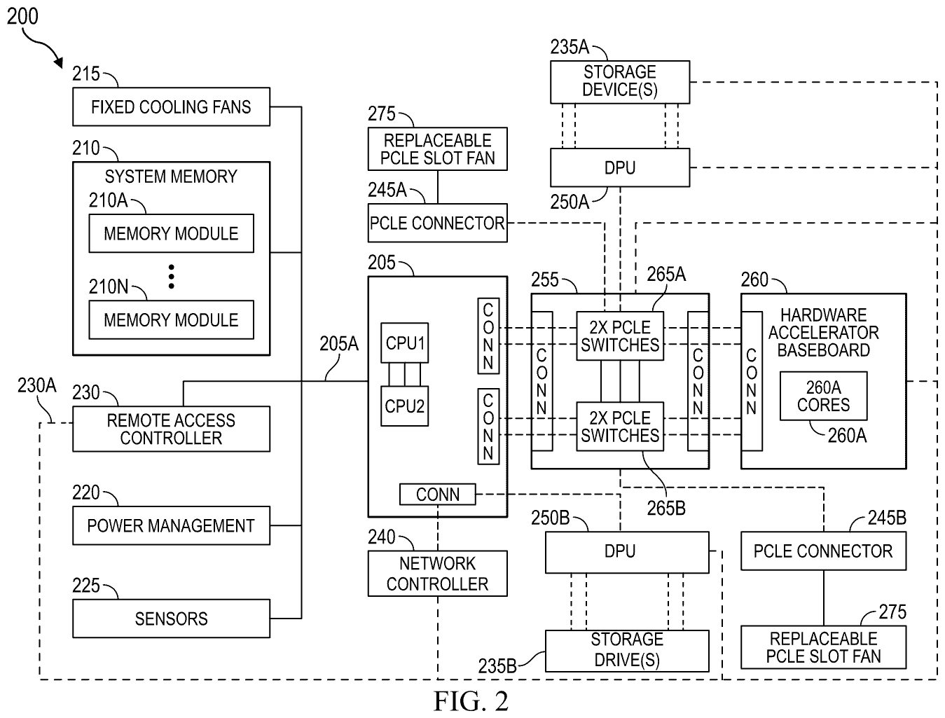

In some embodiments, motherboard sled 105 may be an IHS such as described with regard to IHS 200 of FIG. 2. Accordingly, motherboard sled 105 may include a variety of processing and data storage components. Utilizing these capabilities, motherboard sled 105 may implement a variety of management and security operations for the components of chassis 100. Motherboard sled 105 may also include various I/O controllers that may support various I/O ports, such as USB ports that may be used to support keyboard and mouse inputs and/or video display capabilities. Such I/O controllers may be utilized to support various KVM (Keyboard, Video and Mouse) capabilities that provide administrators with the ability to interface with the chassis 100. Motherboard sled 105 may support various additional functions for use of resources of chassis 100. In some scenarios, motherboard sled 105 may implement tools for managing various other resources available via chassis 100, such as power outputs of power supply unit 135, the network bandwidth provided by network controller 140 and/or PCIe switch 145, and the airflow cooling provided by fixed cooling fans 130 and PCIe-slot fan 150. In particular, motherboard sled 105 may be configured to detect when a PCIe-slot fan 150 has been substituted for replaceable PCIe computing hardware and may additionally configure and manage the operation of PCIe-slot fan 150.

Motherboard sled 105 may be coupled to PCIe-compliant components of chassis 100 via a PCIe switch fabric that may be operated through operations of PCIe switch 145. In some embodiments, the connectors for use in coupling motherboard sled 105 to a PCIe switch 145 include PCIe couplings that support configurable, high-speed data links, where these PCIe links may connect the CPUs 170 of motherboard sled 105 to hardware accelerator sled 115, network controller 140 and some or all of storage drives 120. In some embodiments, the root complex of the PCIe switch fabric may be implemented by the CPU 170 of the motherboard sled 105. Some embodiments may support the root complex of PCIe switch fabric being operated by a hardware accelerator sled 115, thus enabling high-speed memory operations directly by the hardware accelerator sled 115 without relying on the CPUs 170 of the motherboard sled 105. Regardless of whether the PCIe root complex is implemented by the CPU 170 of the motherboard sled 105 or by the hardware accelerator 115, embodiments may support configuration and management of the operation of PCIe-slot fan 150 by the PCIe root complex of the switch fabric implemented using PCIe switch 145.

As illustrated, motherboard sled 105 includes a remote access controller (RAC) 110. As described in additional detail with regard to FIG. 2, remote access controller 110 provides capabilities for remote monitoring and management of the components installed in chassis 100. In support of these monitoring and management functions, remote access controllers 110 may utilize both in-band and sideband (i.e., out-of-band) 110a communications with various components of chassis 100. Remote access controllers 110 may collect various types of sensor data, such as collecting temperature sensor readings that are used in support of airflow cooling of the chassis 100 and of the motherboard sled 105. In addition, remote access controller 110 may implement various monitoring and administrative functions related to motherboard sled 105 that utilize sideband bus connections with various internal components of the motherboard sled 105. In some embodiments, remote access controller 110 may detect capabilities of the replaceable PCIe hardware components that are currently coupled to the chassis 100, and in particular, may detect when a PCIe-slot fan 150 is coupled to chassis 100.

Replaceable hardware accelerator sleds 115 installed in chassis 100 may include one or more processing cores that may be used for delegating a variety of processing tasks, where such delegation may be through programs operating on motherboard sled 105, or via remote systems that interface with the hardware accelerator sled 115 via connections supported by network controller 140 and/or PCIe switch 145. In some embodiments, the processing cores may include multiple GPUs (Graphics Processing Units) 155a-n that may be configured for use in high-performance computing applications. In some embodiments, hardware accelerator sled 115 may include one or more hardware accelerator baseboards, where each accelerator baseboards may itself include one or more accelerator cores. Accordingly, GPUs 155a-n may each represents separate hardware accelerator baseboard that may include multiple GPU cores. In some embodiments, some or all of the accelerator cores available in hardware accelerator sled 115 may be programmable processing cores that can be configured for offloading specific computational functions to the hardware accelerator sled 115.

Hardware accelerator sled 115 may be configured for general-purpose computing or may be optimized for specific computing tasks, such as for implementing machine learning or other artificial intelligence systems. In various embodiments, hardware accelerator sled 115 provides high-performance, computational processing resources that may be used to support a variety of e-commerce, multimedia, entertainment, business and scientific computing applications. Accordingly, hardware accelerator sled 115 may be typically configured with hardware and software that provide leading-edge computational capabilities.

In some scenarios, the capabilities of a chassis 100 may reconfigured through hardware accelerator sleds 115 being added, removed and/or replaced by an administrator. In some embodiments, hardware accelerator sleds 115 may be implemented as PCB-mounted cards and may thus be replaceable PCIe hardware components that may be coupled to PCIe slot connectors of chassis 100, such as PCIe connectors of a backplane. In some embodiments, one or more of the hardware accelerator sleds 115 installed in chassis 100 may be substituted by a PCIe-slot fan 150, thus replacing computing capabilities of the chassis with improved cooling.

As illustrated, chassis 100 also includes one or more storage drives 120 that may be attached to chassis and coupled to connectors supported by components of chassis 100, such as by PCIe switch 145. For instance, storage drives 120 may include multiple solid-state drives (SSDs) 175a-n that are accessed by components of chassis 100 via PCIe switch 145, thus providing low-latency and high-bandwidth access to the SSDs. In some embodiments, one or more of the PCIe storage drives 120 may be implemented as replaceable components that may be added and removed from bays of the chassis 100. In such instances, the chassis may be reconfigured by an administrator by swapping a PCIe storage drive 120 that is implemented on a PCB-mounted card and that conforms to PCIe form factors with a replaceable PCIe-slot fan 150, thus replacing data storage capabilities of chassis 100 with improved cooling.

In addition to the data storage capabilities provided by storage drives 120, chassis 100 may provide access to other storage resources that may be installed as components of chassis 100 and/or may be installed elsewhere within a rack housing the chassis 100, such as within a storage blade to which chassis 100 is coupled. In certain scenarios, such storage resources may be accessed via a SAS expander that is implemented by the motherboard sled 105. The SAS expander may support connections to a number of JBOD (Just a Bunch Of Disks) storage drives 120 that may be configured and managed individually and without implementing data redundancy across the various drives. The additional storage resources may also be at various other locations within a datacenter in which chassis 100 is installed.

As described, the chassis 100 of FIG. 1 includes a network controller 140 that provides network access to the motherboard sled 105 and other components of the chassis. Network controller 140 may include various switches, adapters, controllers and couplings used to connect chassis 100 to a network, either directly or via additional networking components and connections provided via a rack in which chassis 100 is installed, such as by a network switch installed in the chassis. In some embodiments, network controller 140 may be a replaceable component of chassis 100, where a chassis may support concurrent use of multiple network controllers, with each additional network controller adding bandwidth. In some embodiments, such a replaceable network controller 140 may be coupled to the chassis 100 through PCIe connections, such that these network switches may be implemented as PCIe cards that comply with PCIe form factors for replaceable components. In such instances, the chassis may be reconfigured by an administrator by swapping a redundant PCIe network controller 140 that conforms to PCIe form factors with a replaceable PCIe-slot fan 150, thus replacing network capabilities of chassis 100 with improved cooling.

Chassis 100 also includes a power supply unit 135 that provides the components of the chassis with various levels of DC power from an AC power source or from power delivered via a power system provided by a rack within which chassis 100 may be installed. In certain embodiments, power supply unit 135 may be implemented within one or more sleds that provide chassis 100 with redundant, hot-swappable power supply units.

As illustrated, chassis 100 includes fixed cooling fans 130 that are utilized in the airflow cooling of the components installed in chassis 100. These fixed cooling fans 130 may be located at various locations throughout the chassis, such as near ambient air openings of the chassis, near heatsinks or other heat dissipating structures of the chassis and attached to specific computing components installed in the chassis (e.g., dedicated CPU and GPU fans). In some instances, such fixed cooling fans 130 may be replaceable components of chassis to the extent an administrator can remove and replace such cooling fans in response to failures. However, these fixed cooling fans 130 cannot be replaced with computing or data storage components and are instead only replaced with other fans. To that end, the couplings of fixed cooling fans 130 to the thermal management operations of the chassis 100 are limited to providing power and management signals to the fixed cooling fans 130, such as through a sideband I2C 110a connection. As such, fixed cooling fans 130 do not interface with computing buses of the chassis, such as the PCIe switch fabric that may be used in embodiments in management of PCIe-slot fan 150 that may be swapped as a component of the PCIe switch as a substitute for computing, storage or networking hardware of the chassis that conform to PCIe form factors for replaceable hardware.

FIG. 2 is a circuit diagram illustrating certain components of an IHS, according to embodiments, that may be reconfigured to operate using a replaceable PCIe form factor fan. It should be appreciated that although FIGURE described an IHS that is implemented using a motherboard sled 105, a variety of other types of IHSs may be implemented according to the embodiments described herein. For instance, the IHS 200 of FIG. 2 may be a server, such as a rack-mounted server, that may be utilized within a data center or at an edge location. As with the chassis 100 of FIG. 1, the IHS 200 may support PCIe computing, data storage and/or networking hardware that conform to form factors for PCIe cards. In embodiments, one or more of these PCIe computing, data storage and/or networking hardware may be swapped for PCIe-slot fans 275.

Accordingly, IHS 200 may utilize one or more system processors 205, that may be referred to as CPUs (central processing units). In some embodiments, CPUs 205 may each include a plurality of processing cores that may be separately assigned computing tasks. Each of the CPUs 205 may be individually designated as a main processor and as a co-processor, where such designations may be based on delegation of specific types of computational tasks to a CPU 205. In some embodiments, CPUs 205 may each include an integrated memory controller that may be implemented directly within the circuitry of each CPU 205. In some embodiments, a memory controller may be a separate integrated circuit that is located on the same die as the CPU 205. Each memory controller may be configured to manage the transfer of data to and from a system memory 210 of the IHS, in some cases using a high-speed memory interface. The system memory 210 is coupled to CPUs 205 via one or more memory buses that provide the CPUs 205 with high-speed memory used in the execution of computer program instructions by the CPUs 205. Accordingly, system memory 210 may include memory components, such as static RAM (SRAM), dynamic RAM (DRAM), NAND Flash memory, suitable for supporting high-speed memory operations by the CPUs 205. In certain embodiments, system memory 210 may combine persistent non-volatile memory and volatile memory.

In some embodiments, system memory 210 may be implemented, in part or in full, through DMA (Direct Memory Access) operations that are supported by SSD storage drives 235a-b, that may be replaceable PCIe components that comply with PCIe form factors, and may thus be accessible using PCIe NVMe. In configurations of IHS 200 as in FIG. 2, where the root complex of the PCIe switch fabric is implemented by the CPUs 205, these DMA operations on SSD drives 235a-b may be supported through the use of PCIe links provided by a PCIe switches 265a-b, where these PCIe switches 265a-b may be a component of the chassis. In such embodiments, such replaceable PCIe system memory hardware that are implemented as PCIe form factor cards may be replaced by a PCIe form factor fan module, thus swapping system memory capabilities of IHS 200 with improved cooling.

In certain embodiments, the system memory 210 may be comprised of multiple removable memory modules. The system memory 210 of the illustrated embodiment includes removable memory modules 210a-n. Each of the removable memory modules 210a-n may correspond to a printed circuit board memory socket of a motherboard sled 105 that receives a removable memory module 210a-n, such as a DIMM (Dual In-line Memory Module), that can be coupled to the socket and then decoupled from the socket as needed, such as to upgrade memory capabilities or to replace faulty memory modules. Other embodiments of IHS system memory 210 may be configured with memory socket interfaces that correspond to different types of removable memory module form factors, such as a Dual In-line Package (DIP) memory, a Single In-line Pin Package (SIPP) memory, a Single In-line Memory Module (SIMM), and/or a Ball Grid Array (BGA) memory.

IHS 200 may utilize a chipset that may be implemented by integrated circuits that are connected to each CPU 205. All or portions of the chipset may be implemented directly within the integrated circuitry of an individual CPU 205. The chipset may provide the CPU 205 with access to a variety of resources accessible via one or more in-band buses 205a. IHS 200 may also include one or more I/O ports that may be used to couple the IHS 200 directly to other IHSs, storage resources, diagnostic tools, and/or other peripheral components. A variety of additional components may be coupled to CPUs 205 via a variety of busses. For instance, CPUs 205 may also be coupled to a power management unit 220 that may interface with a power system of the chassis 100 in which IHS 200 may be installed. CPUs 205 may collect information from one or more sensors 225 via a management bus.

In certain embodiments, IHS 200 may operate using a BIOS (Basic Input/Output System) that may be stored in a non-volatile memory accessible by the CPUs 205. The BIOS may provide an abstraction layer by which the operating system of the IHS 200 interfaces with hardware components of the IHS. Upon powering or restarting IHS 200, CPUs 205 may utilize BIOS instructions to initialize and test hardware components coupled to the IHS, including both components permanently installed as components of the motherboard of IHS 200 and removable components installed within various expansion slots supported by the IHS 200. The BIOS instructions may also load an operating system for execution by CPUs 205. In certain embodiments, IHS 200 may utilize Unified Extensible Firmware Interface (UEFI) in addition to or instead of a BIOS. In certain embodiments, the functions provided by a BIOS may be implemented, in full or in part, by the remote access controller 230.

In some embodiments, IHS 200 may include a TPM (Trusted Platform Module) that may include various registers, such as platform configuration registers, and a secure storage, such as an NVRAM (Non-Volatile Random-Access Memory). The TPM may also include a cryptographic processor that supports various cryptographic capabilities. In IHS embodiments that include a TPM, a pre-boot process implemented by the TPM may utilize its cryptographic capabilities to calculate hash values that are based on software and/or firmware instructions utilized by certain core components of IHS, such as the BIOS and boot loader of IHS 200. These calculated hash values may then be compared against reference hash values that were previously stored in a secure non-volatile memory of the IHS, such as during factory provisioning of IHS 200. In this manner, a TPM may establish a root of trust that includes core components of IHS 200 that are validated as operating using instructions that originate from a trusted source.

In the IHS 200 of FIG. 2, CPUs 205 are used to operate a PCIe switch fabric that includes each of the PCIe compliant devices of the IHS, such as PCIe switches 265a-b, SSD storage drives 235a-b, network controller 240 and hardware accelerator 260. In various embodiments, some of these PCIe devices may be implemented as PCB expansion cards that are connected to standardized PCIe connectors of the IHS 200. In embodiments, such replaceable PCIe devices may be swapped out by administrators for a PCIe form factor fan 275. In some embodiments, the root complex of the PCIe switch fabric of the IHS 200 may be configured to detect when a PCIe-slot fan 275 has been substituted for replaceable PCIe computing hardware and may additionally configure and manage the operation of one or more PCIe-slot fans 275. The PCIe operations that are implemented by a CPU 205 according to embodiments may operate as the root complex of the PCIe switch fabric of IHS 200 that detects and configures the replaceable fan module.

In the IHS 200 in FIG. 2A, CPUs 205 are coupled to a network controller 240, such as provided by a Network Interface Controller (NIC) card that provides IHS 200 with communications via one or more external networks, such as the Internet, a LAN, or a WAN. In some embodiments, network controller 240 may be support network operations by CPUs 205 through a PCIe coupling accessible by the chipsets of CPUs 205. In some embodiments, network controller 240 may be a replaceable component that may be coupled to the chassis 100 through PCIe connections, such that these network controllers 240 may be implemented as PCIe cards that comply with PCIe form factors. In such instances, the IHS 200 may be reconfigured by an administrator by swapping a redundant PCIe network controller 240 that conforms to PCIe form factors with a replaceable PCIe-slot fan 275, thus replacing network capabilities of IHS 200 with improved cooling.

In the IHS 200 of FIG. 2, PCIe switches 265a-b are coupled via PCIe connections to one or more hardware accelerator cores 260a that are connected to the IHS via one or more removeable hardware accelerators 260. Embodiments may include one or more hardware accelerators 260, such as a GPU baseboard, where each hardware accelerators 260 is coupled to one or more of the PCIe switches 265a-b, and where each hardware accelerator 260 may include one or more cores 260a. Each of the cores 260a may be a programmable processing core and/or hardware accelerator that can be configured for offloading certain functions from CPUs 205, or from a remote CPU. For instance, PCIe switches 265a-b may transfer instructions and data for generating video images between one or more cores 260a and CPUs 205. In processing this graphics data, cores 260a, each of which may be individual GPU cores, may include hardware-accelerated processing capabilities that are optimized for performing streaming calculation of vector data, matrix data and/or other graphics data, thus supporting the rendering of graphics for display on devices coupled either directly or indirectly to IHS 200.

In some embodiments, each hardware accelerator 260 may be a replaceable component that may be coupled to the chassis 100 through PCIe connections, such that these hardware accelerators 260 may be implemented as PCIe cards that comply with PCIe replaceable component form factors. In such instances, the IHS 200 may be reconfigured by an administrator by swapping a PCIe hardware accelerator 260 that conforms to PCIe form factors with a replaceable PCIe-slot fan 275, thus replacing computing capabilities of IHS 200 with improved cooling.

Rather than being used for rendering graphics data for display, GPU cores 260a may instead be used in hardware-accelerated processing of graphics data for other purposes, such as in support of artificial intelligence and machine learning systems. For instance, GPU cores 260a may be used in processing graphical inputs from video and/or camera feeds being utilized in support of machine vision systems. In some instances, GPU cores 260a may process streaming video data in support of on-the-fly machine vision evaluation of live captured video, where captured video data and data resulting from the processing of the video data by the GPU cores 260a may be stored to SSD storage drives 235a-b via PCIe lanes implemented by PCIe switches 265a-b. In other instances, GPU cores 260a may be utilized in offline processing of video data, such as for training of machine learning systems. Such hardware accelerator 260 capabilities may not always be necessary based on the computing functions being implemented by IHS 200. Accordingly, when not needed, such PCIe hardware accelerators 260 may be swapped for additional cooling provided by PCIe-slot fans 275, thus improving cooling of the IHS 200.

Rather than utilize GPUs for cores 260a, in some embodiments, the cores 260a of the hardware accelerator baseboard 260 may instead by DPU (Data Processing Unit) cores. In the same manner as a GPU baseboard, DPU baseboards may be installed within a hardware accelerator sled that is located within a central compartment of a 4 RU processing layer of a chassis 100. As with a GPU baseboard, a DPU hardware accelerator baseboard may provide hardware-accelerated computing in IHS 100, and may also provide optimized implementations for machine learning and other artificial intelligence calculations.

As described, IHS 200 may include a remote access controller 230 that supports remote management of IHS 200 and of various internal components of IHS 200. In certain embodiments, remote access controller 230 may operate from a different power plane from the CPUs 205 and from other components of IHS 200, thus allowing the remote access controller 230 to operate, and management tasks to proceed, while the processing cores of IHS 200 are powered off. As described, various functions provided by the BIOS, including launching the operating system of the IHS 200, may be implemented by the remote access controller 230. In some embodiments, the remote access controller 230 may perform various functions to verify the integrity of the IHS 200 and its hardware components prior to initialization of the operating system of IHS 200 (i.e., in a bare-metal state).

Remote access controller 230 may include a service processor, or specialized microcontroller, that operates management software that provides remote monitoring and administration of IHS 200. Remote access controller 230 may be installed on the motherboard of IHS 200, or may be coupled to IHS 200 via an expansion slot connector provided the IHS. In support of remote monitoring functions, remote access controller 230 may include a dedicated network adapter that may support management connections by remote access controller 230 using wired and/or wireless network technologies.

In some embodiments, remote access controller 230 may support monitoring and administration of various managed devices of an IHS via a sideband bus interface 230a. For instance, messages utilized in device management may be transmitted using I2C sideband bus 230a connections that may be established with each of the managed devices. These managed devices of IHS 200, such as specialized hardware, network controller(s) 240, hardware accelerator 260, hardware accelerator 280, and storage drives 235a-b, may be connected to the CPUs 205 via in-line buses, such as the described PCIe switch fabric, that is separate from the 12C sideband bus 230a connections used by the remote access controller 230 for device management.

As indicated FIG. 2, IHS 200 includes fixed cooling fans 215 that are utilized in the airflow cooling of the components installed in IHS 200. These fixed cooling fans 215 may be located at various locations throughout the IHS 200, such as near ambient air openings of the chassis or enclosure of the IHS, near heatsinks or other heat dissipating structures of the IHS 200 and attached to specific computing components installed in the IHS 200 (e.g., dedicated CPU and GPU fans). In some instances, such fixed cooling fans 215 may be replaceable components of chassis to the extent an administrator can remove and replace such cooling fans in response to failures. However, these fixed cooling fans 215 cannot be replaced with computing or data storage components. To that end, the couplings of fixed cooling fans 215 to the thermal management operations of the IHS 200 are limited to providing power and management signals to the fixed cooling fans 215, such as through a sideband I2C 230a connection. As such, fixed cooling fans 215 do not interface with computing buses of the IHS 200, such as the PCIe switch fabric that may be used in management of PCIe-slot fans 275 that may be swapped as a component of the PCIe switch as a substitute for computing, storage or networking hardware of the IHS 200 that conforms to PCIe form factors for replaceable hardware.

In various embodiments, an IHS 200 does not include each of the components shown in FIG. 2. In various embodiments, an IHS 200 may include various additional components in addition to those that are shown in FIG. 2. Furthermore, some components that are represented as separate components in FIG. 2 may in certain embodiments instead be integrated with other components. For example, in certain embodiments, all or a portion of the functionality provided by the illustrated components may instead be provided by components integrated into the one or more processor(s) 205 as a systems-on-a-chip.

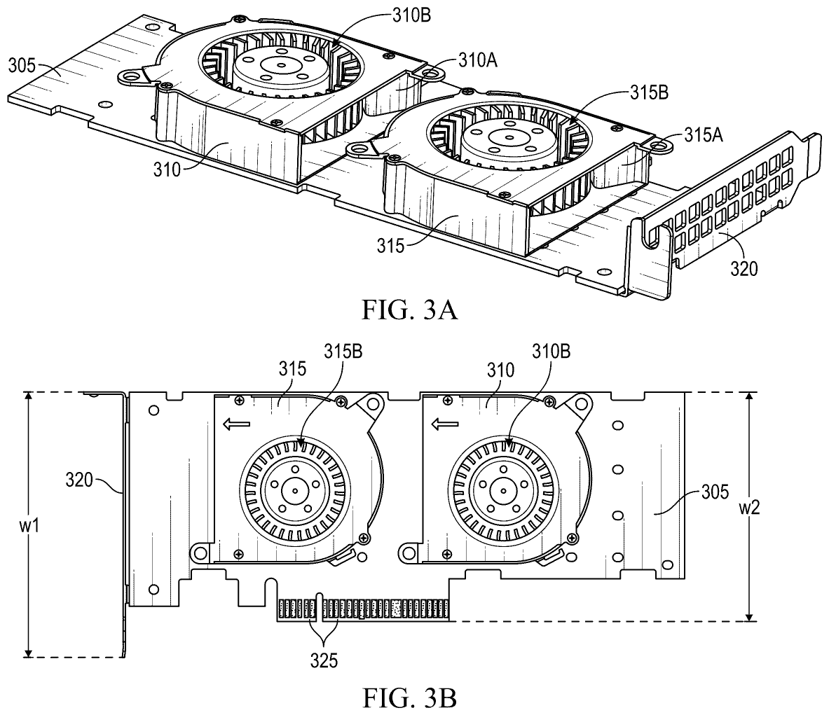

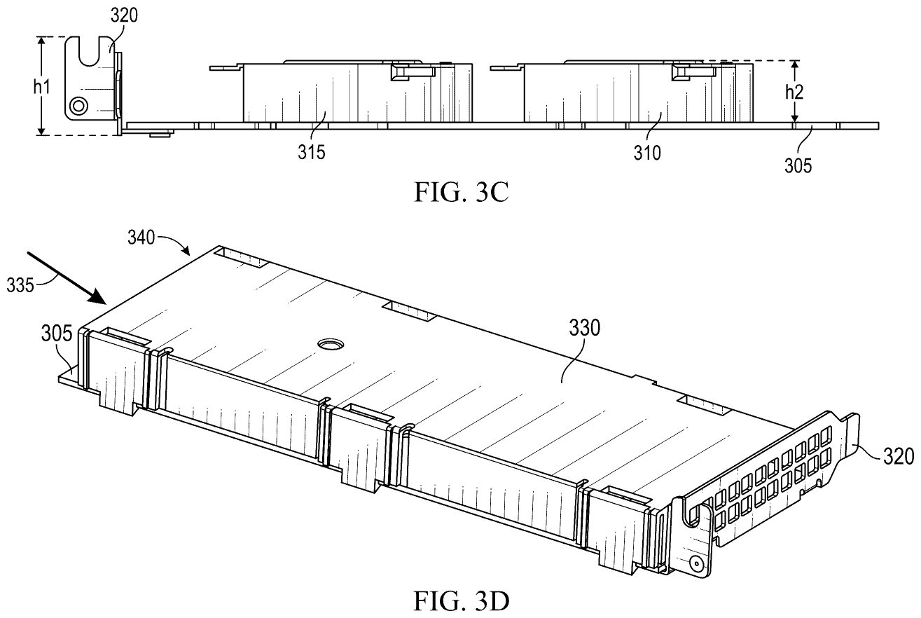

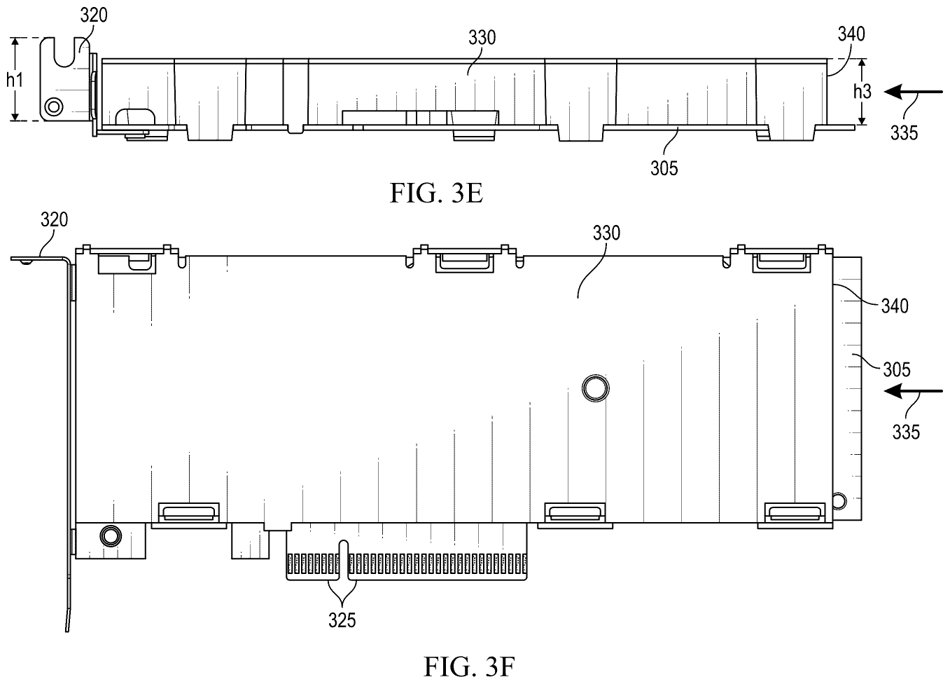

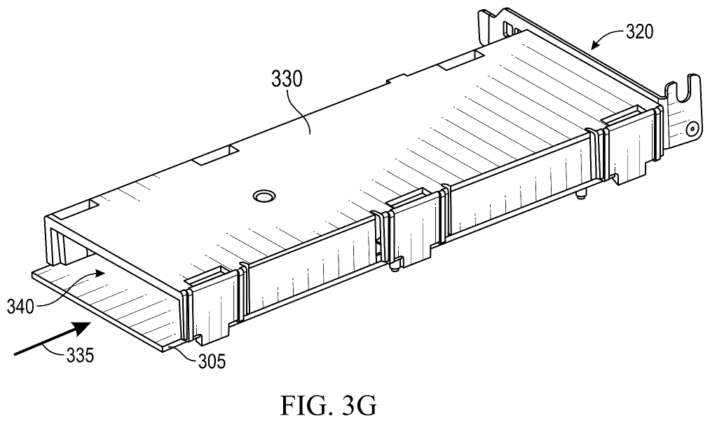

FIG. 3A is a front-perspective view illustration of a replaceable PCIe fan module 300, according to embodiments. As described, a PCIe fan module 300 may be substituted for replaceable PCIe components of an IHS 200 and/or chassis 100, where these PCIe components conform to PCIe form factor standards for replaceable components. In conformance with such form factor standards, PCIe fan module 300 includes a bracket 320 for securing the PCIe fan module to the chassis 100 and/or IHS 200. Utilizing a standard bracket 320, the PCIe fan module 300 may be installed in any PCIe slot of a chassis 100 and/or IHS 200 that correspond to the type of bracket 320 in use. In particular, the PCIe fan module 300 may be swapped for replaceable PCIe hardware of the chassis 100 and/or IHS 200.

As illustrated, the PCIe fan module 300 may be constructed from a PCB (Printed Circuit Board) 305. In embodiments, one or more centrifugal (i.e., radial) fans 310, 315 may be mounted to the PCB. In the illustrated embodiment, two centrifugal fans 310, 315 are utilized, but other embodiments may include a single centrifugal fan, with other embodiments including more than two centrifugal fans that may be mounted in various configurations on the PCB 305.

When operated, the centrifugal fans 310, 315 may draw air from inside the chassis 100 and/or IHS 200 via inlets 310B, 315B in the top of each of the fans. Once installed, the inlets 310B, 315B of the centrifugal fans 310, 315 may draw surrounding heated air from within the chassis. The heated air that is drawn by each of the centrifugal fans 310, 315 is redirected orthogonally through exhausts 310A, 315A that are positioned facing the bracket 320. As illustrated, the bracket 320 may include openings through which the heated air drawn by the centrifugal fans 310, 315 is redirected, thus ventilating heated air from within the interior of the chassis 100 and/or IHS 200 in which the PCIe fan module 300 is installed.

FIG. 3B is a top-view illustration of a replaceable PCIe fan module 300, according to embodiments. In the top-view of FIG. 3B, dimensions of the replaceable fan module are illustrated, including the width of the bracket 320, identified as the dimension w1, and the width of the PCB 305, identified as dimension w2. In conformance with PCIe form factor standards for replaceable hardware, these width dimensions of the bracket 320 and PCB 305 may be identical to dimensions of PCIe computing, storage and networking components utilized by an chassis 100 and/or IHS 200. In particular, the bracket 320 of width w1 may allow the PCIe fan module 300 to be fastened in the chassis 100 and/or IHS 200 in slots that are usable by replaceable PCIe hardware.

The PCB 305 of width w2 may further allow the PCIe fan module 300 to be fastened in the chassis 100 and/or IHS 200 in slots that are usable by replaceable PCIe hardware. In particular, through the use of a PCB of width w2, the PCIe fan module 300 may be inserted into a PCIe slot of the chassis 100 or IHS 200 and pushed into a PCIe connector supported by the chassis 100 or IHS 200. As with the PCIe hardware of the chassis 100 and/or IHS 200 with which the PCIe fan module 300 may be swapped, the PCB 305 may include multiple sets of pins 325 that are received by the PCIe connector of the chassis 100 and/or IHS 200.

In some embodiments, the PCB 305 may include only pins 325 that conform to the PCIe form factor and that are necessary for operation of the centrifugal fans 310, 315 that are mounted to the PCIe fan module 300. Accordingly, the pins 325 included in embodiments may include one or more power pins, including pins for voltage, common and ground circuits to be supported by the PCIe fan module 300. The pins 325 included in the embodiments may also include one or more data pins of the PCIe form factor pinout, where the data pins may be used by management components of the chassis 100 and/or IHS 200 to configure and operate the centrifugal fans 310, 315. In some embodiments, the root complex of the PCIe switch fabric of the chassis 100 and/or IHS 200 may detect the coupling of a PCIe fan module 300 based on detecting the coupling of pins 325 to a PCIe connector. Through interrogation via these pins 325, the root complex of the PCIe switch fabric may identify the cooling capabilities of the centrifugal fans 310, 315 and may configure operation of the fans.

In the top-down view of the embodiment illustrated in FIG. 3B, the centrifugal fans 310, 315 are mounted in a serial configuration with the rear centrifugal fan 310 directly behind the front centrifugal fan 315. In other embodiments the rear centrifugal fan 310 may be offset from the front centrifugal fan 315 such that a portion of the exhaust 310a of the rear fan blows directly out the exit provided by the openings in the bracket 320. In other embodiments, the rear centrifugal fan 310 may be mounted to the PCB 305 at a different angle than the front centrifugal fan 315, thus directing a portion of the exhaust 310a of the rear fan around the front fan 310.

FIG. 3C is a side-view illustration of a replaceable PCIe fan module, according to embodiments. In the side-view, the height h1 of the bracket 320 is illustrated, where this height is selected in accordance with PCIe form factor dimensions for chassis 100 and/or IHS 200 slots for replaceable PCIe hardware. The side-view of FIG. 3C also illustrates the centrifugal fans 310, 315 that are mounted to the PCB 305. As indicated, the height h2 of the centrifugal fans 310, 315 may be selected to be within the PCIe form factor dimensions. In the illustrated embodiment, the centrifugal fans 310, 315 are of the same size. In some embodiments, the rear centrifugal fan 310 may be larger than the front centrifugal fan 315, such that a portion of the exhaust of the rear centrifugal fan 310 is not obstructed by the front fan. In some embodiments, the rear centrifugal fan 310 may include an exhaust vent that directs the exhaust airflow of the rear fan around the front centrifugal fan 315. In some embodiments, the centrifugal fans 310, 315 may be raised from the PCB via standoffs and may have lower and upper inlets, or only lower inlets.

FIG. 3D is a perspective-view illustration of a replaceable PCIe fan module that includes a shroud 330, according to embodiments. FIG. 3D depicts the same perspective of the PCIe fan module 300 as FIG. 3A, but with a shroud 330 now attached to the PCB 305. As illustrated, embodiments may include a shroud 330 that attaches to the PCB 305 and creates a compartment that surrounds the centrifugal fans 310, 315, except for an open exhaust end of the shroud that borders the openings in the bracket 320 and except for an open inlet 340 end of the shroud that is opposite the bracket. Through these open ends of the shroud, heated air from within the chassis may be vented in direction 335 by the fans 310, 315 of the replaceable fan module and forced out of the openings in bracket 320.

In some embodiments, the shroud 330 may be attached to the PCB 305 through prestressed snap fit clips (e.g., cantilever snap fit joints) of the shroud that may be snapped into corresponding structures along the edges of the PCB. As illustrated in FIG. 3D, the top of the shroud 300 may include openings adjacent to each of the snap fit clips. Through these openings in the top of the shroud 330, an administrator may insert a tool that can be leveraged against the shroud itself to apply outward pressure on each snap fit clip, allowing it to be released from the edge of the PCB. The shroud may be selected from suitable plastic, metals and alloys that promote the ability of the PCIe fan module 300 to draw heated air from within the chassis 100 and/or IHS 200 and to redirect this heat through the openings in bracket 320.

FIG. 3E is a side-view illustration of a replaceable PCIe fan module that includes a shroud 330, according to embodiments. In the side-view, the height h1 of the bracket 320 is again illustrated. The side-view of FIG. 3E now illustrates the shroud 330 that encloses the centrifugal fans 310, 315 that are mounted to the PCB 305. As indicated, the height h3 of the shroud may be selected to be within the PCIe form factor dimensions. In the illustrated embodiment, the shroud is of the same height throughout. In other embodiments, different geometries of shrouds may be utilized for promoting the venting of exhaust airflow of the rear centrifugal fan 310. As indicated, the operation of centrifugal fans 310, 315 draws heated air in directed 335 from within the chassis and into opening 340 in the rear of the shroud.

FIG. 3F is a top-view illustration of a replaceable PCIe fan module that includes a shroud 305, according to embodiments. In the top-view of FIG. 3F, the width of the shroud 305 is illustrated relative to the width w2 of the PCB 305. As illustrated, the width of the shroud is selected to allow for the pins 325 of the PCB 305 to remain exposed and thus for the PCIe fan module 300 to be connected to a PCIe connector of the chassis 100 and/or IHS 200. In the embodiment of FIG. 4F, a rectangular geometry of the shroud 330 is illustrated. Other embodiments may utilize shrouds of different geometries that promote the venting of exhaust airflow of the rear centrifugal fan 310. As indicated, the operation of centrifugal fans 310, 315 draws heated air in directed 335 from within the chassis and into opening 340 in the rear of the shroud.

FIG. 3G is a rear-perspective view illustration of a replaceable PCIe fan module that includes a shroud, according to embodiments. In the rear-perspective view, the inlet 340 opening in the rear of the shroud 330 is visible. As indicated, heated air that is drawn in direction 335 into inlet 340 of the shroud is ventilated out of the openings in bracket 320 by the operation of centrifugal fans 310, 315. In the illustrated embodiment, the inlet 340 of the shroud 330 is in the rear of the PCB 305 on the end opposite the bracket 320. In other embodiments, the rear of the shroud may be closed and the inlet may be an opening in the top of the shroud, opposite the side of the shroud that is adjacent to the pins of the PCB, thus drawing in heated air from a different area of the interior of the chassis when compared to the illustrated embodiment with the inlet 340 at the end of the shroud. In the illustrated embodiment, the inlet 340 in the rear of the shroud 330 is a rectangular opening. Other embodiments may utilize different geometries of inlets in the shroud by which air may be drawn from specific areas within the interior of the chassis 100.

It should be understood that various operations described herein may be implemented in software executed by logic or processing circuitry, hardware, or a combination thereof. The order in which each operation of a given method is performed may be changed, and various operations may be added, reordered, combined, omitted, modified, etc. It is intended that the invention(s) described herein embrace all such modifications and changes and, accordingly, the above description should be regarded in an illustrative rather than a restrictive sense.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. A replaceable fan module for installation in a chassis including one or more IHSs (Information Handling Systems), the replaceable fan module comprising:
a first centrifugal fan mounted on a printed circuit board, wherein an exhaust of the first centrifugal fan is oriented towards openings in a bracket for fastening the printed circuit board within a PCIe slot of the chassis; and
the printed circuit board comprising a plurality of pins for electrically coupling the replaceable fan module to the PCIe slot of the chassis, wherein the pins are arranged according to a PCIe form factor, and wherein the replaceable fan module is activated and configured for operation upon coupling of the pins to a connector of the PCIe slot.

2. The replaceable fan module of claim 1, wherein the replaceable fan module is substituted by an administrator for a PCIe computing component that is removed from the PCIe slot of the chassis.

3. The replaceable fan module of claim 1, wherein the replaceable fan module is connected to a PCIe switch fabric operating on the chassis upon the coupling to the connector of the PCIe slot.

4. The replaceable fan module of claim 1, wherein an inlet on top of the first centrifugal fan draws air from within the chassis and directs the drawn air orthogonally via the exhaust towards the openings in the bracket.

5. The replaceable fan module of claim 1, further comprising a shroud that is attached to the printed circuit board and that surrounds the first centrifugal fan, except for an exhaust opening oriented towards the openings in the bracket and except for an inlet opening that is oriented towards an interior of the chassis once the replaceable fan module is coupled to the PCIe slot.

6. The replaceable fan module of claim 5, wherein the inlet opening in the shroud is oriented towards an end of the printed circuit board that is opposite from the bracket.

7. The replaceable fan module of claim 1, further comprising a second centrifugal fan mounted on the printed circuit board, wherein an exhaust of the second centrifugal fan is oriented towards the openings in the bracket.

8. The replaceable fan module of claim 7, wherein the replaceable fan module is configured for operation of the first centrifugal fan and of the second centrifugal fan upon coupling of the pins to the connector of the PCIe slot.

9. A chassis housing one or more Information Handling Systems (IHSs), the chassis comprising:
a plurality of PCIe slots;
a motherboard comprising one or more CPUs (Central Processing Units) configured to operate as a root complex for a PCIe switch fabric comprising PCIe components coupled to the plurality of PCIe slots; and
a replaceable fan module comprising a first centrifugal fan mounted on a printed circuit board, wherein an exhaust of the first centrifugal fan is oriented towards openings in a bracket for fastening the printed circuit board within any of the plurality of PCIe slots of the chassis; and the printed circuit board comprising a plurality of pins for electrically coupling the replaceable fan module to the chassis, wherein the pins are arranged according to the PCIe form factor, and wherein the replaceable fan module is activated and configured for operation upon coupling of the pins to a connector of any of the plurality of PCIe slots.

10. The chassis of claim 9, wherein the replaceable fan module is substituted by an administrator for a PCIe computing component that is removed from the PCIe slot.

11. The chassis of claim 9, wherein an inlet on top of the first centrifugal fan draws air from within the chassis and directs the drawn air orthogonally via the exhaust towards the openings in the bracket.

12. The chassis of claim 9, wherein the replaceable fan module further comprises a shroud that is attached to the printed circuit board and that surrounds the first centrifugal fan, except for an exhaust opening oriented towards the openings in the bracket and except for an inlet opening that is oriented towards an interior of the chassis once the replaceable fan module is coupled to the PCIe slot.

13. The chassis of claim 12, wherein the inlet opening in the shroud is oriented towards an end of the printed circuit board that is opposite from the bracket.

14. The chassis of claim 9, further comprising a second centrifugal fan mounted on the printed circuit board, wherein an exhaust of the second centrifugal fan is oriented towards the openings in the bracket.

15. A method for airflow cooling of a chassis housing one or more Information Handling Systems (IHSs), the method comprising:
operating a first PCIe card as part of a PCIe switch fabric of the chassis, wherein the first PCI card is coupled to a PCIe slot of the chassis;
physically decoupling the first PCI form factor components from the PCIe slot of the chassis;
physically coupling a replaceable fan module in the PCIe slot of the chassis from which the first PCIe card has been physically decoupled, wherein the replaceable fan module comprises a first centrifugal fan mounted on a printed circuit board, wherein an exhaust of the first centrifugal fan is oriented towards openings in a bracket for fastening the printed circuit board within the PCIe slot of the chassis, and wherein the printed circuit board comprises a plurality of pins for electrically coupling the replaceable fan module to a connector of the PCIe slot; and
operating the replaceable fan module to ventilate heated air from within the chassis.

16. The method of claim 15, wherein the replaceable fan module is substituted by an administrator for a PCIe card comprising a computing component that is removed from the PCIe slot.

17. The method of claim 15, wherein an inlet on top of the first centrifugal fan draws air from within the chassis and directs the drawn air orthogonally via the exhaust towards the openings in the bracket.

18. The method of claim 15, wherein the replaceable fan module further comprises a shroud that is attached to the printed circuit board and that surrounds the first centrifugal fan, except for an exhaust opening oriented towards the openings in the bracket and except for an inlet opening that is oriented towards an interior of the chassis once the replaceable fan module is coupled to the PCIe slot.

19. The method of claim 18, wherein the inlet opening in the shroud is oriented towards an end of the printed circuit board that is opposite from the bracket.

20. The method of claim 15, further comprising a second centrifugal fan mounted on the printed circuit board, wherein an exhaust of the second centrifugal fan is oriented towards the openings in the bracket.
